(19) United States
(12) Patent Application Publication
(10) Pub. No.: US 2007/0096253 A1
(43) Pub. Date: May 3, 2007

(54) Integrated capacitor with a high breakdown voltage

(75) Inventors: Joaquin Torres, Saint Martin Le Vinoux (FR); Alexis Farcy, Le Ravoire (FR)

Correspondence Address: SEED INTELLECTUAL PROPERTY LAW GROUP PLLC, 701 FIFTH AVENUE, SUITE 5400, SEATTLE, WA, 98104-7092, US

(73) Assignee: STMicroelectronics (Crolles 2) SAS, Crolles (FR)

(21) Appl. No.: 11/436,117

(22) Filed: May 17, 2006

(30) Foreign Application Priority Data
May 18, 2005 (FR) 05 04988

(51) Int. Cl. H01L 29/00

(52) U.S. Cl. 257/532

(57) ABSTRACT

A capacitor incorporated into an integrated electronic circuit comprises two plates and a series of intermediate layers placed between the plates. The intermediate layers are alternately insulating layers and conducting layers, and each conducting layer is electrically isolated from the rest of the circuit. Such a capacitor may have a high breakdown voltage.

### BACKGROUND OF THE INVENTION

1. Field of the Invention

The present invention relates to an integrated electronic circuit incorporating a capacitor having a high breakdown voltage. It also relates to a process for producing such a capacitor.

2. Description of the Related Art

Many integrated electronic circuits incorporate capacitors of the MIM (metal-insulator-metal) type. Examples that may be mentioned include memory circuits, analog circuits and circuits operating at high frequency. An MIM capacitor comprises an insulating portion of dielectric material inserted between two metal portions forming the plates of the capacitor.

Now, some circuits require capacitors of high capacitance. To obtain a sufficient capacitance without increasing the dimensions of a capacitor, the dielectric material of the insulating portion that is inserted between the plates is selected so as to have a high dielectric permittivity. In particular, it is known to use alumina (Al₂O₃), tantalum oxide (Ta₂O₅), zirconium oxide (ZrO₂), hafnium oxide (HfO₂) or titanium strontium oxide (SrTiO₃) instead of silica (SiO₂) as dielectric material in a capacitor. However, the portions of these dielectric materials of high permittivity that are produced exhibit many defects, because the process for producing these materials is less well controlled than the use of silica. The observed defects comprise, for example, impurities of the material, inclusions, crystal defects, microvoids and/or microcracks. Capacitors that incorporate these portions of dielectric material therefore have a low breakdown voltage, which constitutes a limitation in the use of such capacitors. In certain cases, they also have a high leakage current.

The breakdown voltage of a capacitor integrated into an electronic circuit is often a specified parameter in the specification for this circuit. It is measured, in a known manner, so as to check whether it is above the value specified in the specification. Such a measurement forms part of the tests that are routinely carried out during the fabrication of a new circuit and that are subsequently repeated in order to check the production quality during mass-production of the circuit. Usually, the desired breakdown voltage for an MIM-type integrated capacitor is around 10 to 15 volts.

Now, the portions of dielectric material of high permittivity that are introduced into MIM-type capacitors have an electric field strength below that of standard dielectric materials. Typically, the breakdown voltage of a capacitor provided with a portion of dielectric material of high permittivity is less than 10 volts. To increase the breakdown voltage of such a capacitor, it is known to increase the thickness of the portion of dielectric material that is inserted between the plates. However, the capacitance of the capacitor then becomes too low for the function of the capacitor in the circuit.

### BRIEF SUMMARY OF THE INVENTION

One embodiment of the present invention provides a new type of integrated capacitor, in which a sufficient capacitance and a high breakdown voltage are combined.

One embodiment of the invention proposes an integrated electronic circuit incorporating a capacitor, the capacitor comprising:

two approximately parallel conducting plates; and

a series of intermediate layers placed between and in parallel to the plates, comprising at least one conducting layer and electrically insulating layers, each conducting layer being arranged between two insulating layers.

Furthermore, each intermediate conducting layer is electrically isolated so that this layer is at a floating electric potential during operation of the circuit.

The inter-plate gap of a capacitor according to one embodiment of the invention is therefore divided into several parts, along the direction perpendicular to the plates, which correspond to the intermediate insulating layers. Two different insulating layers are separated by an intermediate conducting layer, the electric potential of which is left floating. This electric potential therefore varies in value depending on the electric voltage applied between the plates. Each intermediate insulating layer is subjected to an electric potential difference, between the two faces of this layer that are parallel to the plates of the capacitor, which is equal to a fraction of the electric voltage existing between the two plates. The electric voltage between the two plates may then be higher than the breakdown voltage of each intermediate insulating layer, which would be measured between the two intermediate conducting layers located against this insulating layer on each side thereof. In particular, it is possible for the potential difference between the two faces of each insulating layer not to reach the breakdown value for this layer, although the total electric voltage measured between the two plates of the capacitor is high. Thus, the apparent breakdown voltage of the entire capacitor, which is measured between the two plates, is increased. In particular, the capacitor may have a breakdown voltage, measured between its two plates, which is greater than 5 volts, or even greater than 10 volts.

Furthermore, each intermediate insulating layer may consist of a dielectric material that has a high dielectric permittivity. In particular, at least one of the insulating layers may include a portion of a material having a relative dielectric permittivity of 6 or higher. This material may for example be alumina, tantalum oxide, zirconium oxide, hafnium oxide or titanium strontium oxide.

Preferably, the surfaces of each intermediate conducting layer that are located against insulating layers are made of a material that has a metallic-type electrical conductivity. In this case, owing to the respective electronic structures of the metal layers and the insulating layers, the breakdown voltage of each insulating layer may be increased by choosing the material with metallic conductivity appropriately. In particular, each intermediate layer of the capacitor may for example be made of copper (Cu), aluminum (Al), platinum (Pt), ruthenium (Ru) or titanium nitride (TiN). The capacitor obtained is then of the MIM type.

The series of intermediate layers may comprise at least three conducting layers. The breakdown voltage of the capacitor may then be of the order of three times the breakdown voltage of each intermediate insulating layer taken individually, especially when the intermediate insulating layers are identical.

Furthermore, each intermediate insulating layer has preferably a thickness of less than 10 nanometers in the direction perpendicular to the plates of the capacitor. Indeed, when using equipment commercially available at the present time for forming insulating layers, an insulating layer will have a number of defects liable to be the origin of a breakdown that increases with the thickness of this layer. Limiting the thickness of each insulating layer to 10 nanometers therefore contributes to achieving a high breakdown voltage of the capacitor, measured between the two plates.

One embodiment of the invention proposes a process for producing a capacitor in an integrated electronic circuit, of the type described above. Such a process comprises the following steps:

a) forming a lower plate layer on the circuit;

b) depositing in succession above the lower plate layer, a series of alternating electrically insulating intermediate layers and electrically conducting intermediate layers, said series starting and finishing with insulating layers; and

c) forming an upper plate layer above the series of intermediate layers.

Furthermore, the circuit is produced so that each intermediate conducting layer is electrically isolated.

According to a first method of implementing the invention, the process further includes the following step, effected after step c):

d) etching the upper plate layer, each intermediate layer and optionally the lower plate layer in succession outside a zone of the circuit corresponding to the capacitor.

According to a second method of implementing the invention, the process further includes a preliminary step of forming a cavity in the circuit. The lower plate layer, the intermediate layers and the upper plate layer are then formed in succession in the cavity, so as to be conformal with the bottom and lateral sides of the latter.

Optionally, such a process may also include the following step, carried out after step c):

d) polishing the circuit so as to remove respective portions of the upper plate layer, of the intermediate layers and optionally of the lower plate layer outside the cavity.

In these two methods of implementation, the process may further include the following additional step, carried out after the corresponding step d):

e) passivating respective edges and ends of the intermediate conducting layers, which are formed in step d), so as to eliminate any electrical conduction path terminating on at least one of the intermediate conducting layers.

Thus, any short circuit that might appear between two intermediate conducting layers of the capacitor during the etching or polishing step d) is eliminated. Such a step e) guarantees in particular that the intermediate conducting layers will have a floating electric potential during operation of the circuit. Step e) may include in particular the oxidation of the edges or ends of the intermediate conducting layers by bringing the circuit into contact with an oxidizing fluid.

### BRIEF DESCRIPTION OF THE SEVERAL VIEWS OF THE DRAWINGS

Other features and advantages of the present invention will become apparent in the description below of two non-limiting embodiments, with reference to the appended drawings in which:

FIGS. 1a-1d and 2a-2b illustrate various steps in the production of an integrated electronic circuit with a capacitor according to two embodiments of the invention.

### DETAILED DESCRIPTION OF THE INVENTION

For the sake of clarity, the elements shown in these figures have not been drawn to scale. N denotes a direction perpendicular to the surface of a substantially plane substrate of the circuit. The direction N is directed upwards in the figures and the words “on”, “under”, “lower” and “upper” used hereafter refer to this orientation. Furthermore, identical references in the various figures denote identical elements or those that have identical functions. Moreover, the description is limited hereafter to a succession of elementary steps in the production of the integrated circuit that allows the invention to be reproduced. Each elementary step, which is considered as known per se, will not be discussed in detail.

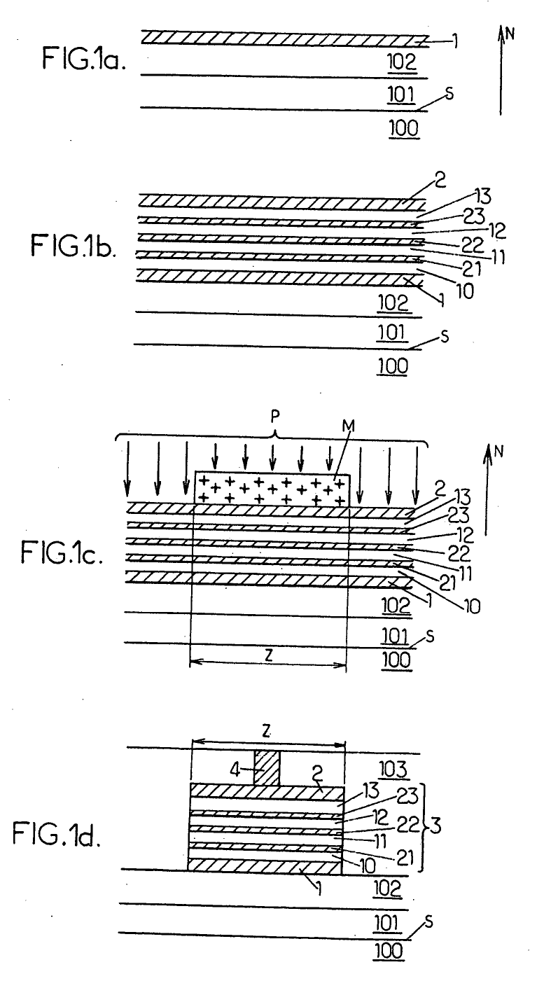

As shown in FIG. 1a, a substrate 100 for an integrated electronic circuit being fabricated is covered on its upper surface S with a premetallization layer 101 and with at least one metallization layer 102. A metal layer 1 is then deposited on the layer 102, using a process known to those skilled in the art, such as the ALD (atomic layer deposition) process. As an example, the layer 1 may be made of aluminum (Al) and may have a thickness of 50 nm (nanometers). It may be deposited in the form of what is called a “full wafer” coating—after deposition, it therefore covers the upper surface of the electronic circuit entirely.

Next, layers 10, 21, 11, 22, 12, 23 and 13 are deposited in succession on the layer 1 (FIG. 1b). The layers 10-13 are made of a dielectric material, such as tantalum oxide (Ta₂O₅). The layers 21-23 are made of a metallic material, such as aluminum. Each layer 10-13 or 21-23 preferably has a thickness of between 5 and 10 nm along the direction N. Finally a metal layer 2, which may be similar to the layer 1, is formed on the last insulating layer 13. The layers 2, 10-13 and 21-23 may each cover the entire circuit.

Next, the layers 2, 21-23, 10-13 and 1 are etched, starting from the upper surface of the circuit, outside a zone Z of the circuit that corresponds to the dimensions of the capacitor parallel to the surface S of the substrate 100. To do this, a resist mask M is formed by lithography on the circuit, and a plasma flux P is accelerated against the upper surface of the circuit, parallel to the direction N but in the opposite direction thereto (FIG. 1c). Such an etching process is well known and is called “dry etching”. The nature of the ions contained in the etching plasma may be selected so as to rapidly remove the materials of the various metallic or insulating layers. Optionally, a stop layer (not shown), for example made of silicon nitride (Si₃N₄), may have been placed between the layers 102 and 1 in order to stop the progression of the etching front before it penetrates the layer 102. In this way, the layers 2, 13, 23, 12, 22, 11, 21, 10 and then 1 are removed in succession outside the zone Z. After this etching operation, residual portions of these layers only remain in the zone Z. The resist mask M is then removed (FIG. 1d).

It is possible that the etching of the layers 1, 2, 10-13 and 21-23 leaves debris of conducting material on one edge of one of the residual portions of the intermediate layers. Because of the small thicknesses of the layers 10-13 and 21-23, such debris may cause a short circuit between two residual portions of the layers 21-23, or between one of these portions of layers 21-23 and the residual portion of one of the layers 1, 2. It is therefore advantageous to apply an oxidation treatment to the circuit, in order to make the exposed edges of the residual portions of the layers 21-23 electrically insulating. Such a treatment also passivates the edges of the residual portions of the layers 1 and 2 and also the exposed upper surface of the residual portion of layer 2.

The fabrication of the integrated circuit can then continue in a known manner. In particular, a layer 103 of insulating material may be deposited on the circuit so as to cover the multilayer of the residual portions of the layers 1, 2, 10-13 and 21-23. One or more electrical connections 4 are then produced through the layer 103, especially so as to connect the residual portion of layer 2 to other electronic components of the circuit (these not being shown).

The residual portions of the layers 1 and 2 form the lower and upper plates of the capacitor, respectively. In the present case, these are planar and parallel to the surface S of the substrate 100. The inter-plate gap, bearing reference 3 in FIG. 1d, is filled with the residual portions of the layers 10-13 and 21-23. For this reason, these residual portions of layers are denoted in short by “intermediate layers” of the capacitor. The intermediate layers 10-13, which are insulating, together constitute the dielectric of the capacitor. Said dielectric is therefore divided into several parts along the direction N, which are separated by the conducting intermediate layers 21-23. Each insulating intermediate layer 10-13 is therefore located between a plate and a conducting intermediate layer, or between two conducting intermediate layers.

The inventors have found that, contrary to common reasoning, the electric field corresponding to the breakdown voltage of a single insulating layer sandwiched between two conducting layers may become higher when the thickness of the insulating layer decreases. This unexpected change in the electric breakdown field is attributed to defects in the insulating material that are more numerous when the layer is thicker. The currently available deposition processes allow very thin layers to be formed with a small quantity of defects. The breakdown voltage of the insulating layer, denoted by V₀, therefore seems to be mainly determined by the electronic properties of the insulating material and by those of the material of each conducting layer located on either side of the insulating layer. According to the discovery by the inventors, a suitable choice of metallic material for each conducting layer allows a high value of the breakdown voltage V₀ of the insulating layer to be achieved. The Fermi level of the metallic material, when it is compared with the limits of the valence and/or conduction bands of the insulating material, seems to be an important parameter for this choice.

Each of the insulating layers 10-13 is subjected, between its two faces perpendicular to the direction N, to a fraction of the electric voltage existing between the plates 1 and 2. This fraction corresponds to the ratio of the thickness of this insulating layer to the sum of the thicknesses of all the insulating layers 10-13. Breakdown of the capacitor, which occurs by one of the layers 10-13 breaking down, therefore takes place when that fraction of the electric voltage present between the faces of this layer reaches the breakdown value for this layer. Thus, if the intermediate insulating layers 10-13 are identical, the breakdown voltage of the capacitor, measured between the plates 1 and 2, is approximately equal to 4×V₀. In general, if the inter-plate gap 3 contains n identical insulating layers separated pairwise by conducting layers, n being an integer, the breakdown voltage of the capacitor is approximately n×V₀. In the capacitors produced according to the invention, a V₀ of between 3 and 5 volts has been measured. The invention therefore makes it possible to produce capacitors having breakdown voltages of higher than 10 volts, or even higher than about 20 volts when n is equal to or greater than 3.

The inventors have also found that possible effects of spikes in the electric field present in the capacitor, between the plates 1 and 2, are limited when the inter-plate gap 3 is divided by the conducting layers. This limitation thus helps to prevent the capacitor from breaking down for a defined electric voltage applied between the plates 1 and 2.

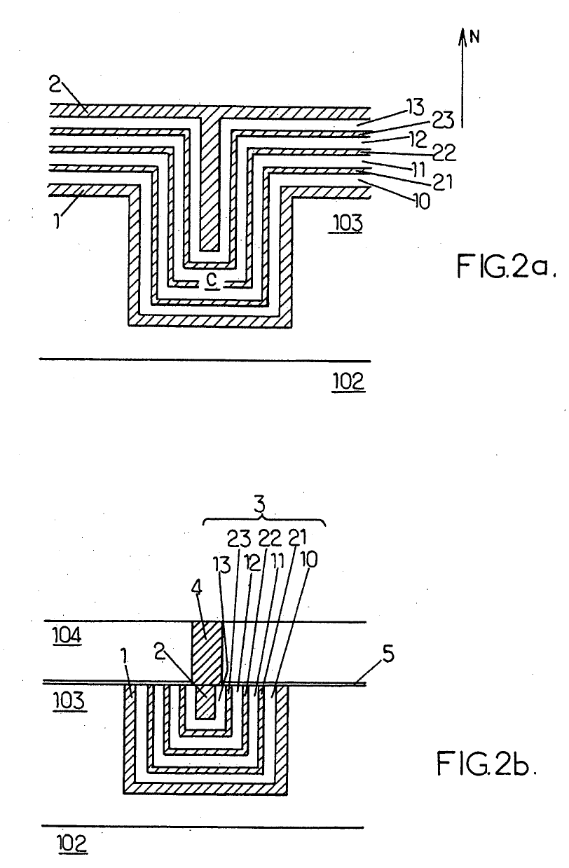

FIGS. 2a and 2b illustrate a second embodiment of the invention, which will now be described. It will be assumed that the metallization layers 102 and 104 of the integrated electronic circuit have already been produced. A cavity C (FIG. 2a) is hollowed out in the layer 104 from the upper surface thereof. The dimensions of the cavity C parallel to the surface of the substrate 100 may be defined, in a known manner, by a lithography mask. The depth of the cavity C, which may for example be 5 microns, may be set by the duration of the etching step.

Layers 1, 10, 21, 11, 22, 12, 23, 13 and 2 are deposited in succession on the circuit, using electrically insulating and conducting materials alternately. Suitable deposition conditions are adopted for the layers 1, 10-13 and 21-23 so as to obtain conformal coatings. In other words, the layers obtained have substantially parallel faces that reproduce the shape of the cavity C. Each plate and each intermediate layer of the capacitor constitutes a conformal coating placed inside the cavity C, which coating extends over the bottom and the lateral sides of the latter. Such deposition conditions are known to those skilled in the art, in particular for ALD (atomic layer deposition) and CVD (chemical vapor deposition) processes. To give an example, the layer 1 may have a thickness of 20 nanometers, the layers 10-13 and 21-23 may each have a thickness of between 5 and 10 nanometers, and the layer 2 may have a thickness sufficient to fill the cavity C. When the damascene process is used, the layers 10-13 may be based on silica (SiO₂) and the layers 21-23 may be made of copper (Cu).

Next, the upper surface of the circuit is polished so as to remove those parts of the layers 1, 2, 10-13 and 21-23 present above the layer 104 outside the cavity C (FIG. 2b). This polishing may be carried out using the CMP (chemical-mechanical polishing) process.

Advantageously, the upper ends of the residual portions of the layers 1, 2 and 21-23 located at the opening of the cavity C are made electrically insulating by oxidation. Furthermore, a continuous passivation layer 5 may be deposited on the circuit in order to complete the insulation of these ends. The layer 5 covers in particular the exposed upper ends of the residual portions of the layers 1, 2, 10-13 and 21-23 that are flush with the opening of the cavity C. The layer 5 may for example be made of silicon oxide (SiO₂), silicon nitride (Si₃N₄) or silicon carbide (SiC). Its thickness may for example be 1 nanometer.

An additional metallization layer 105 is then deposited on the layer 5 and an electrical connection 4 may be formed through the layers 105 and 5 in order to connect the plate 2 of the capacitor to other components of the circuit.

When the damascene process is used to produce the capacitor, a single lithography step is therefore sufficient to produce the capacitor within the circuit.

Of course, many adaptations may be introduced into the embodiments of a circuit with a capacitor that have just been described. Among these, mention may particularly be made of:

the number of intermediate conducting layers may be varied in order to obtain a particular value of the breakdown voltage of the capacitor;

each conducting layer of the capacitor, whether an intermediate layer or one intended to form a plate, may be made up from several elementary layers. In particular, a three-film multilayer, consisting of a copper film deposited between two titanium nitride (TiN) films, may be used to constitute each intermediate conducting layer or each plate;

in the first embodiment described in relation to FIGS. 1a-1d, the lower plate of the capacitor may have dimensions greater than those of the intermediate layers and of the upper plate, parallel to the surface of the substrate, especially for reducing effects due to the edges of the electric field present in the capacitor;

the capacitor may be produced in the substrate of the circuit or in the first layer of connections above the surface of the substrate, called the premetallization layer; and

a capacitor according to the second embodiment of the invention may have a form consisting of meanders in a plane parallel to the surface of the substrate. The capacitor may thus have a high capacitance, without occupying too large a portion of the surface of the substrate.

From the foregoing it will be appreciated that, although specific embodiments of the invention have been described herein for purposes of illustration, various modifications may be made without deviating from the spirit and scope of the invention. Accordingly, the invention is not limited except as by the appended claims.

1. An integrated electronic circuit, comprising:
a capacitor that includes:
two approximately parallel conducting plates; and
a series of intermediate layers placed between and approximately in parallel to the plates, comprising at least three conducting layers and several electrically insulating layers, each conducting layer being arranged between two of the insulating layers, respectively,
wherein each intermediate conducting layer is electrically isolated so that said layer is at a floating electric potential during operation of the circuit.

2. The circuit according to claim 1 wherein the capacitor has a breakdown voltage, measured between the two plates of the capacitor, of more than 5 volts.

3. The circuit according to claim 2 wherein the breakdown voltage, measured between the two plates of the capacitor, is greater than 10 volts.

4. The circuit according to claim 1 wherein each intermediate conducting layer has surfaces that are located against insulating layers and are made of a material having a metallic-type electrical conductivity.

5. The circuit according to claim 1 wherein each intermediate insulating layer has a thickness of less than 10 nanometers in a direction perpendicular to the plates of the capacitor.

6. The circuit according to claim 1 wherein at least one of the intermediate insulating layers includes a portion of a material having a relative dielectric permittivity of 6 or higher.

7. The circuit according to claim 1 wherein the capacitor is positioned in at least one metallization layer or premetallization layer of the circuit.

8. The circuit according to claim 1 wherein each plate of the capacitor is substantially planar.

9. The circuit according to claim 1 wherein each plate and each intermediate layer of the capacitor constitutes a conformal coating placed inside a cavity of said circuit and extends over a bottom and lateral sides of said cavity.

10. A process for producing a capacitor in an integrated electronic circuit, comprising the following steps:
a) forming a lower plate layer on the circuit;
b) depositing in succession above the lower plate layer, a series of alternating electrically insulating intermediate layers and electrically conducting intermediate layers, said series starting and finishing with insulating layers, and comprising at least three conducting intermediate layers; and
c) forming an upper plate layer above the series of intermediate layers,
the circuit being produced so that each conducting intermediate layer is electrically isolated.

11. The process according to claim 10, which further includes the following step:
d) etching the upper plate layer and each intermediate layer in succession outside a zone of the circuit corresponding to the capacitor.

12. The process according to claim 11, which further includes the following step:
e) passivating respective edges of the intermediate conducting layers, which are formed in step d), so as to eliminate any electrical conduction path terminating on at least one of the conducting intermediate layers.

13. The process according to claim 10, which further includes a preliminary step of forming a cavity in the circuit, and wherein the lower plate layer, the intermediate layers and the upper plate layer are formed in succession in the cavity, so as to be conformal with the bottom and lateral sides of said cavity.

14. The process according to claim 13, which further includes the following step:
d) polishing the circuit so as to remove respective portions of the upper plate layer and of the intermediate layers outside the cavity.

15. The process according to claim 14, which further includes the following step:
e) passivating ends of the intermediate conducting layers that are formed in step d) so as to eliminate any electrical conduction path terminating on at least one of the conducting intermediate layers.

16. A capacitor, comprising:
two spaced apart conducting plates;
three spaced apart intermediate conducting layers positioned between the conducting plates; and
insulating material positioned between and completely surrounding the intermediate conducting layers, the insulating material insulating the intermediate conducting layers from the conducting plates.

17. The capacitor of claim 16 wherein the capacitor has a breakdown voltage, measured between the two plates, of more than 10 volts.

18. The capacitor of claim 16 wherein the insulating material includes four intermediate insulating layers respectively interspersed with the intermediate conducting layers.

19. The capacitor of claim 18 wherein each intermediate insulating layer has a thickness of less than 10 nanometers in a direction perpendicular to the plates of the capacitor.

20. The capacitor of claim 16 wherein the plates are substantially planar and parallel to one another.

21. The capacitor of claim 16 wherein a first one of the plates and the intermediate conducting layer are unshaped and surround a second one of the plates.
